(19) United States
(12) Patent Application Publication
(10) Pub. No.: US 2025/0055464 A1
(43) Pub. Date: Feb. 13, 2025

(54) ARBITRARY PHASE SHIFT WITH PHASE-COHERENT MODULATION OF A TRANSMITTED RADIO FREQUENCY SIGNAL

(71) Applicant: NORDIC SEMICONDUCTOR ASA, Trondheim (NO)

(72) Inventors: Daniel James RYAN, Trondheim (NO); Ruben UNDHEIM, Trondheim (NO)

(21) Appl. No.: 18/719,159

(22) PCT Filed: Dec. 13, 2022
(86) PCT No.: PCT/EP2022/085619

§ 371 Date: Jun. 12, 2024

(30) Foreign Application Priority Data
Dec. 14, 2021 (NO) 20211504

(51) Int. Cl. H03L 7/085; H03L 7/099; H04B 1/403

(52) U.S. Cl. CPC H03L 7/085; H03L 7/099; H04B 1/403; H03L 2207/50

(57) ABSTRACT

A method for controlled phase adjustment and coherent modulation in a radio frequency transceiver is provided. The radio frequency transceiver comprises an analogue circuitry for transmitting and receiving radio frequency signals and an all-digital phase locked loop controlled by a Phase Locked Loop, PLL, Control unit (200). The method comprises: receiving a phase shift, and based thereon, deriving a corresponding digital control signal; inputting the digital control signal to the PLL Control unit (200), the control signal defining a temporary iteration pattern of delays to be used by a configurable delay block, DTC (240); locking a radio frequency oscillator signal of a Digital Controlled Oscillator (220) in the phase locked loop to the temporary iteration pattern of delays; adjusting the phase of the frequency signal in digital circuitry, until the signal phase matches the phase shift defined by the digital control signal.

The present invention relates to a method and device providing precise control of an arbitrary phase shift of a transmitted radio frequency signal while keeping coherent modulation when switching between radio frequencies.

### BACKGROUND AND PRIOR ART

A radio frequency (RF) device can be used for estimating distance from a device to a target. Estimation of distance can be useful for different purposes, such as for instance triggering proximity-based actions on the device. A distance can be determined by analysing radio frequency signals traveling from the device and back to the device.

For some ranging applications, it would be useful to have full control of how a radio signal is shaped when transmitted.

The present invention relates to a method and device for ranging and bearing applications, and more specifically where ranging and bearing can be performed with arbitrary phase shift while keeping coherent modulation of a transmitted radio frequency signal.

There are different ways of doing ranging. One method is two called way ranging (2WR) were two devices, an initiator and a reflector, performs several steps of sending and receiving tones which are different in each step. Each device takes phase measurements, and phase measurements from both sides in each step are added to cancel the time offset between devices, leaving 2× the channel phase.

Another method is asymmetric 2WR, which is similar to 2WR, but in some of the steps only one of the devices sends a tone, which is the same device, e.g. the reflector. In steps where both devices send and receive a tone, the phase measurements are collected at the initiator and subtracted to cancel the channel phase, leaving 2× the time offset. This time offset is used at the initiator to cancel the time offset on the 1-way tones.

Conventional approaches to distance estimation using 2WR RF signals involve phase-based ranging techniques, in which a first radio frequency device referred to as an initiator, transmits a radio signal in the form of a constant tone using a local oscillator (LO). A second radio frequency device, referred to as a reflector having a local oscillator (LO) at the same frequency as the first radio frequency, measures a first phase difference ψᵢᵣ, between its LO and the constant tone. Then the roles are switched, where the reflector sends a constant tone, while the initiator measures a second phase difference ψᵣᵢ. The sum of the two phase-differences is related to the distance between the first radio frequency device and the second radio frequency according to:

$$ψ ( f ) = {ψ}_{ir} ( f ) + {ψ}_{ri} ( f ) \approx \frac{4 π fd}{v}$$

where f is the shared LO frequency, v is the speed of light in the medium.

By taking phase measurements over at least two frequencies, e.g. f₁, f₂ it is possible to determine the distance according to:

$$d = \frac{v ( ψ ( {f}_{1} ) - ψ ( {f}_{2} ) )}{4 π ( {f}_{1} - {f}_{2} )}$$

In order to improve the quality and prevent ambiguities of a distance estimate in the presence of phase error, phase measurements can be performed on all possible channels within a frequency band, and a distance is determined using a linear regression solving for the slope of the phase difference as a function of f.

A Bluetooth device can be used for ranging. The device comprises a RF transceiver and uses a radio technology called frequency-hopping operating at frequencies on the 2.4 GHz band, i.e. different channels each having different frequencies covering the whole 2.4 GHz band. Bluetooth ranging uses a technique referred to as Multi Carrier Phase Difference (MCPD) ranging where distance measurements are performed on different channels, i.e. frequencies.

For Bluetooth ranging, I/Q data, i.e. phase data, measured by a reflector is sent back to an initiator using standard Bluetooth packets, and the initiator calculates a distance.

In inline 2WR, the phase of the I/Q data measured at the reflector can be applied to a local oscillator (LO) prior to the reflector's transmission. This avoids the latency of sending the I/Q data in a packet.

A requirement of 2WR is that the transmitted phase and the receiver's reference phase must be coherent within one frequency step. The difference in phase of the LO between any two points within a step is then predictable.

FIG. 1 illustrates an example of a circuit maintaining phase coherency. This is called the Zero-IF mode reception which is the simplest way to maintain phase coherency. In this implementation, the transmitted signal from the initiator (fTX,INIT) and the transmitted signal from the reflector (fTX,REFL) have the same frequency, in the example shown in FIG. 1, the frequency is 2440 MHz. Radio signals are transmitted via an antenna connected to a Balun 100 for optimizing the signals. The Balun 100 is connected to a power amplifier (PA) 120 for transmitting signals, and a low noise amplifier (LNA) 110 for receiving radio signals. A modulator 160 generates a carrier signal which is input to a local oscillator (LO) Phase Reference Generator 150. The signal is input to a phase locked loop (PLL) 140 which in turn outputs a signal with same phase as the input signal received from the LO Phase Reference Generator 150. The output signal from the PLL 140 is input to the PA 120 and to a mixer 130. The LO frequency applied to the received signal of the initiator (fRXLO,INIT) and the received signal from the reflector (fRXLO,REFL) is in this implementation the same as the frequencies of the transmitted signals from the initiator and reflector, i.e. in this example 2440 MHz.

This implementation ensures that phase difference of the transmitted signal and the reflected signal output from the mixer can be used for Multi Carrier Phase Difference Ranging (MCPD ranging). This output signal is input to an anti-aliasing filer (AAF) 170 to optimize the signal for sampling in the analogue to digital converter (ADC) 180. The resulting digital signal is processed an optimized in digital filters 190 and finally magnitude, phase and frequency estimation is performed in an estimation unit 195 for deriving ranging information between the initiator and the reflector.

In this design, a received radio signal is demodulated using synchronous detection driven by the local oscillator (LO) to ensure that both transmitter and receiver stages use the same frequency generated by same source e.g. from a phase locked loop.

In some cases, changing the phase of a transmitted radio frequency signal by an arbitrary amount is useful. This may be used for inline two-way ranging (2WR) where a reflector adjusts its transmitted phase to match an incoming signal. In addition, it has been proposed as a method of obfuscation for security purposes.

U.S. Pat. No. 10,985,787 B1 describes a system and method for generating phase-coherent signalling when ranging between a transmitting node and a receiving node during wireless communication. Phase adjustment of a signal to be transmitted from the receiving node is performed such that the phase commensurate with at least an amount of a phase of a signal transmitted by the transmitting node and received at the receiving node.

The present invention enables precise control of the phase of a radio frequency signal transmitted from a transceiver by inputting a required phase on an input of a of the transceiver. The required phase on the transmitted radio frequency signal is then set over a few time steps.

The ability to have precise control of the phase of a transmitted radio signal is useful for certain ranging or bearing applications where we want full control of the shape of the transmitted radio signal.

According to the invention, precise control of the phase of a transmitted radio signal from a transmitter is enabled by using all-digital (AD) circuitry in the PLL. By using AD-PLL, more of the internals of the PLL is accessible, monitorable and controllable via the digital circuitry.

### SUMMARY OF THE INVENTION

The present invention is a method and device for controlled phase adjustment and coherent modulation of a transmitted radio frequency signal of a radio transceiver. The radio transceiver comprises an analogue circuitry for transmitting and receiving radio frequency signals. It further comprises a digital circuitry with a configurable delay block connected between a reference oscillator and a phase comparator for controlling the phase of the transmitted radio frequency signal.

Phase detection is performed in an All-digital PLL (AD-PLL) enabled by using digital filters and Digital Controlled Oscillator (DCO), e.g. an LC oscillator controlled by digital signals.

By using a digital configurable delay block between the reference oscillator and the phase comparator, an AD-PLL can lock to non-integer multiples, i.e. fractional frequencies, of the reference oscillator.

The AD-PLL is adapted to lock to non-integer multiples of a reference frequency by iterating over a pattern of delays thereby staying locked to a fractional frequency of the reference frequency.

More specifically, and in a first aspect, the present invention provides method for controlled phase adjustment and coherent modulation of a transmitted radio frequency signal of a radio frequency transceiver, the radio frequency transceiver comprises an analogue circuitry for transmitting and receiving radio frequency signals, an all-digital phase locked loop controlled by a Phase Locked Loop Control unit, PLL Control unit, the phase locked loop further comprises circuitry with a configurable delay block (DTC) connected to a reference frequency oscillator, a phase comparator, a Time-to Digital Converter (TDC), the configurable delay block, DTC, being adapted to lock to non-integer multiples of a reference frequency by iterating over a pattern of delays thereby staying locked to a fractional frequency of the reference frequency.

The method comprises the following steps:
receiving a phase shift to be applied to the transmitted radio frequency signal, and based on the received phase shift, deriving a corresponding digital control signal;
inputting the digital control signal to the PLL Control unit via an interface, the control signal defining a temporary iteration pattern of delays to be used by the configurable delay block, DTC;
locking a radio frequency oscillator signal of a Digital Controlled Oscillator, DCO, in the phase locked loop to the temporary iteration pattern of delays, and
adjusting the phase of the frequency signal in the digital circuitry, until the signal phase matches the phase shift defined by the digital control signal, to provide a coherent phase adjusted transmitted radio frequency signal.

The method according to the invention provides precise control of the phase of a radio frequency signal transmitted from a transceiver when inputting a required phase on an input of the transceiver. When a specific phase is input, the required phase on the transmitted radio frequency signal is set over a few time steps.

In one embodiment, the digital control signal defines a total phase change value and a phase change value per clock cycle, i.e. the rate of change.

In one embodiment, the phase change is input via a user interface device. This can be any type of user interface providing input control signals values. The user interface is connected to a CPU or similar device connected to the PPL Control unit.

In one embodiment, the phase change is input from a peer communication device.

In one embodiment, the transmitted radio frequency signal is used for phase-based ranging. Changing the phase of a transmitted radio frequency signal by an arbitrary amount may useful for inline two-way ranging where a reflector adjusts its transmitted phase to match an incoming signal.

In a second aspect, the invention provides a radio frequency transceiver device for controlled phase adjustment and coherent modulation of a transmitted radio frequency signal, the radio frequency transceiver comprises an analogue circuitry for transmitting and receiving radio frequency signals, an All-Digital Phase Locked Loop, AD PLL, being connected to the analogue circuitry, and comprising a configurable delay block, DTC, being connected to a reference frequency oscillator, a phase comparator and a Time-to Digital Converter, TDC, a where the configurable delay block, DTC, is adapted to lock to non-integer multiples of a reference frequency by iterating over a pattern of delays thereby staying locked to a fractional frequency of the reference frequency, the All-Digital Phase Locked Loop, AD PLL, where the digital circuitry further comprises a Phase Locked Loop Control unit adapted to:
receiving a digital control signal, representing a requested phase shift to be applied to the transmitted radio frequency signal, where the control signal comprises a temporary iteration pattern of delays with another incrementation value to be used by the configurable delay block, DTC, and where the radio frequency oscillator signal in the phase locked loop is locked to the temporary iteration pattern of delays,
adjusting the phase of the frequency signal in the digital circuitry, until the signal phase matches the phase shift defined by the digital control signal, to provide a coherent phase adjusted transmitted radio frequency signal.

The invention enables precise control of adjusting the phase of the RF oscillator signal to a specified angle. The angel or number of degrees can be set on user request via software or via a peer communication, or it can be automatically set to an angle based on retrieved pre-configured values.

### BRIEF DESCRIPTION OF THE DRAWINGS

The following drawings are appended to facilitate the understanding of the invention.

FIG. 1 shows an example of prior art transceiver with a PLL comprising analogue components in the signal path.

FIG. 2 illustrates an all-digital PLL of a transceiver according to the invention.

### DETAILED DESCRIPTION OF THE INVENTION

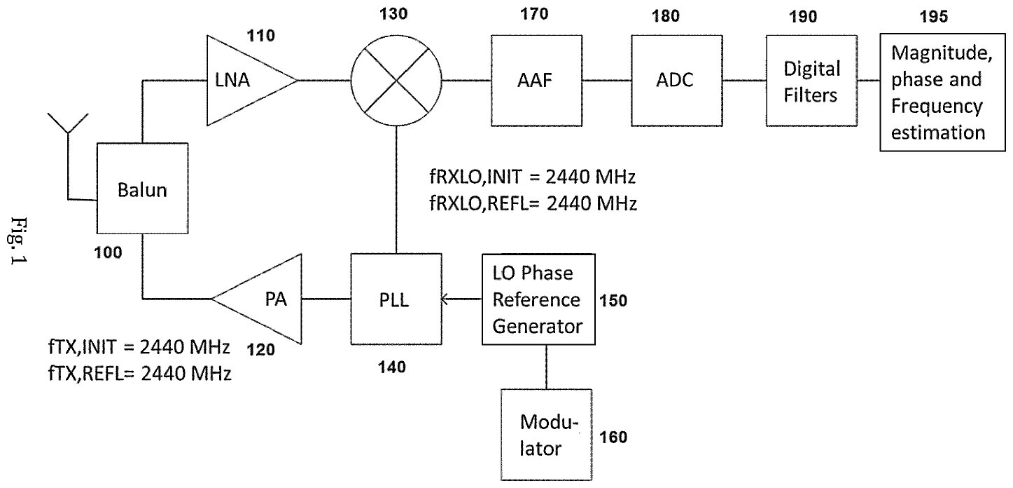

In the following, the invention will be described in detail with reference to the drawings, where FIG. 1 has already been discussed in the background section above.

As described above, the embodiment of the Phase Locked Loop (PLL) shown in FIG. 1 comprises both analogue and digital modules in the signal path of the transmitted and received signals of a transceiver.

By using all-digital circuitry in the phase looked loop (AD-PLL), more of the internals of the PLL are accessible for monitoring and controlling via the digital circuitry.

By adding digital control, the phase of the RF oscillator signal can be moved a specified angle via a software request, e.g. according to number of degrees.

This may be useful for certain ranging or bearing applications where full control of the shape of a transmitted radio signal is required. This is made possible with AD-PLL which can lock to non-integer multiples, also called fractional frequencies, of a reference oscillator by using a configurable delay block, between the reference oscillator and a phase comparator.

When changing the phase of a transmitted radio frequency, the PLL needs to stay locked to a fractional frequency of the local oscillator (LO). This is achieved by implementing a configurable delay block (DTC), also called Digital-to-Time Converter, that is using a sequence of time delays which depends only on a fractional frequency of the LO being the Phase Reference Generator input to the PLL. Locking to a fractional frequency is achieved by letting the DTC iterate over a pattern of time delays whenever the PLL needs to stay locked to a specific fractional frequency.

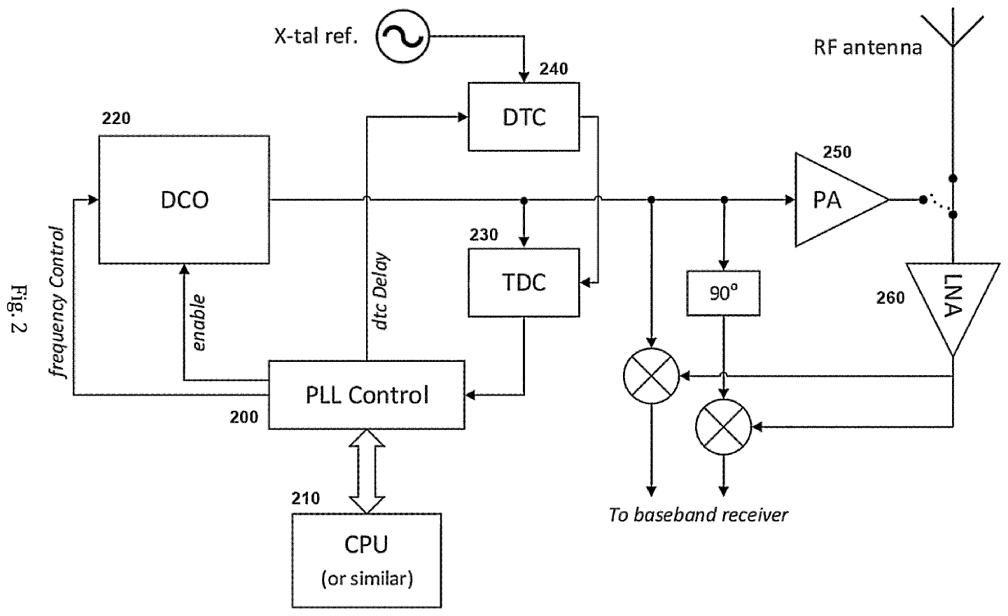

FIG. 2 illustrates an all-digital PLL comprised in a transceiver according to the invention. The PLL comprises a PLL Control unit 200 with an interface to a CPU or similar 210 device for communicating with the PLL Control unit 200. The PLL Control unit 200 is connected to a Digital Controlled Oscillator (DCO) 220, and further connected to Time-to-Digital Converter (TDC) 230 and to a configurable delay block (DTC) 240. The TDC 230 is also connected to the DTC 240.

The DCO 220 is also connected to the Time-to-Digital Converter (TDC) 230 as well as analogue circuitry comprising power amplifier (PA) 250 for transmitting RF signals, a low noise amplifier (LNA) 260 and a baseband receiver for receiving radio signals.

The invention is further defined by a method for controlled phase adjustment of a transmitted radio frequency signal of a radio transceiver for providing coherent modulation of the transmitted radio frequency signal. The radio transceiver comprises an analogue circuitry for transmitting and receiving radio frequency signals, a digital circuitry comprising a configurable delay block (DTC) 240 connected between a reference oscillator (X-tal ref.) and a phase comparator, the configurable delay block being adapted to lock to non-integer multiples of a reference frequency by iterating over a pattern of delays thereby staying locked to a fractional frequency of the reference frequency.

The method comprises different steps performed in a phase locked loop of the digital circuitry of the radio transceiver.

A first step is inputting, on the digital circuitry, a phase shift to be applied to the transmitted radio frequency signal. A control signal defines a total phase change value and a phase change value in per clock cycle, i.e. the rate of change.

During normal operation, the DTC will use a sequence of time delays which depends only on the fractional frequency of the PLL. If for instance the reference frequency is 32 MHz, and the operating frequency is 2401 MHZ, the fractional frequency is 1 MHz—and so on. The time delays will increment proportionally with the fractional frequency every clock cycle: DTC_time(n+1)=DTC_time(n)+fractional_frequency. This expression is very simplified since it does not include that DTC_time wraps around every period of the operating frequency.

When a phase change has been requested, the DTC will for a certain number of clock cycles use a sequence of time delays which depends on the fractional frequency+a number (k). This gives DTC_time(n+1)=DTC_time(n)+fractional_frequency+k.

A separate accumulator keeps track of how long it will need to apply this pattern:

$$accumulator = accumulator + k$$

where k=(accumulator<(requested_phase_change−k_max))? k_max requested_phase_change−accumulator

k_max is set low enough such that the PLL will not lose its lock, and high enough such that it does not take too much time do the phase change.

As mentioned, the control signal defining a phase shift can be given as a phase request signal which is input via a user interface connected to a CPU or similar device 210 connected to the PPL Control unit 200. In another embodiment, a phase request can be performed by a peer communication device requesting a specific phase to be used.

Based on a phase shift input, a corresponding control signal is derived from software running in the CPU 210, and input to the configurable delay block (DTC) 240 via a digital interface.

The control signal defines a temporary iteration pattern of delays to be used by the configurable delay block (DTC) 240.

The temporary iteration pattern being different from an iteration pattern corresponding to a phase shift currently used by the DTC 240 if the input defines another phase shift.

The radio frequency oscillator signal in the phase locked loop is then locked to the temporary iteration pattern of delays. The duration the signal is locked to the temporary iteration pattern is defined by the requested phase change and the max phase change speed (k_max).

The phase of the frequency signal is then adjusted in the digital circuitry. This is done, as described above, until the phase of the signal matches the phase shift defined by the input control signal. The described method will provide a coherent phase adjusted transmitted radio frequency signal.

In one scenario, the invention adds the possibility for software to request that the DTC 240 will, for a short time, iterate with another pattern in order for the phase to effectively get a net movement of an exactly specified number of degrees. If the software wants the radio signal to turn 35 degrees for example, a digital state machine will apply the necessary changes to the DTC control pattern to make that happen automatically over some clock cycles.

A register interface in the PLL Control unit 200 receives inputs from the software via a CPU 210 running the software. The inputs are the total phase change in degrees, with several decimals giving high resolution, and how many degrees to move the phase per clock cycle.

In another scenario, the same circuitry, in a slightly different configuration, can also be used to reset the phase to an absolute value. This may be useful for instance when going to another RF channel while keeping the phase locked. Simply resetting the phase abruptly is risky because the PLL may go out of its bounds and lose a lock on a signal. However, gradually adjusting the phase over a few clock cycles to effectively achieve a phase reset may prevent that the PLL loses a lock on a signal.

The present invention provides full control of changing a phase of a transmitted radio frequency signal by spreading the phase change over multiple clock cycles, and where this is performed in digital circuitry. This solution can easily be executed by software with a simple register interface to digital circuitry providing precise timing.

The arbitrary phase shift provided by the invention can be used for different purposes. For instance to allow phase coherence between High Accuracy Distance Measurement (HADM) steps for the purposes of asymmetric 2WR using inline 2WR where the timing and RF frequencies are not integer multiples of the time interval between frequency steps, in this case the phase returns to initial phase value at the start of each frequency step.

The invention further allows to correct for a modulation, e.g. in the form of a packet used for Ranging with Round Trip Time (RTT) measurements within the event. If the AD-PLL frequency is modulated, phase coherence is lost. However, if the accumulated phase shift over duration of the modulated data is recorded it can be corrected by applying a phase shift, at the end of a Bluetooth packet.

1. A method for controlled phase adjustment and coherent modulation of a transmitted radio frequency signal of a radio frequency transceiver, wherein the radio frequency transceiver comprises an analogue circuitry for transmitting and receiving radio frequency signals, an all-digital phase locked loop controlled by a Phase Locked Loop Control unit, PLL Control unit, the phase locked loop further comprises circuitry with a configurable delay block, DTC connected to a reference frequency oscillator, a phase comparator, a Time-to Digital Converter, TDC, the configurable delay block, DTC, being adapted to lock to non-integer multiples of a reference frequency by iterating over a fixed pattern of delays thereby staying locked to a fractional frequency of the reference frequency, wherein the method comprises the following steps:
receiving a phase shift to be applied to the transmitted radio frequency signal, and based on the received phase shift, deriving a corresponding digital control signal,
inputting the digital control signal to the PLL Control unit via an interface, the control signal defining a temporary iteration pattern of delays to be used by the configurable delay block, DTC,
locking a radio frequency oscillator signal of a Digital Controlled Oscillator, DCO, in the phase locked loop to the temporary iteration pattern of delays,
adjusting the phase of the frequency signal in the digital circuitry, until the signal phase matches the phase shift defined by the digital control signal, to provide a coherent phase adjusted transmitted radio frequency signal.

2. The method according to claim 1, where the digital control signal defines a total phase change value and a phase change value per clock cycle.

3. The method according to claim 2, where the phase change is input via a user interface device.

4. The method according to claim 2, where the phase change is input from a peer communication device.

5. The method according to claim 1, where the transmitted radio frequency signal is used for phase-based ranging.

6. A radio frequency transceiver device for controlled phase adjustment and coherent modulation of a transmitted radio frequency signal, wherein the radio frequency transceiver comprises an analogue circuitry for transmitting and receiving radio frequency signals, an All-Digital Phase Locked Loop, AD-PLL, being connected to the analogue circuitry, and comprising a configurable delay block, DTC, being connected to a reference frequency oscillator, a phase comparator and a Time-to Digital Converter, TDC, where the configurable delay block, DTC, is adapted to lock to non-integer multiples of a reference frequency by iterating over a fixed pattern of delays thereby staying locked to a fractional frequency of the reference frequency, the All-Digital Phase Locked Loop, AD-PLL,
wherein the digital circuitry further comprises a Phase Locked Loop Control unit adapted to:
receiving a digital control signal, representing a requested phase shift to be applied to the transmitted radio frequency signal, where the control signal comprises a temporary iteration pattern of delays to be used by the configurable delay block, DTC, and where the radio frequency oscillator signal in the phase locked loop is locked to the temporary iteration pattern of delays,
adjusting the phase of the frequency signal in the digital circuitry, until the signal phase matches the phase shift defined by the digital control signal, to provide a coherent phase adjusted transmitted radio frequency signal.
